(19) United States
(12) Patent Application Publication
(10) Pub. No.: US 2017/0301849 A1
(43) Pub. Date: Oct. 19, 2017

(54) THERMOELECTRIC MODULE

(71) Applicant: Mahle International GmbH, Stuttgart (DE)

(72) Inventor: Thomas Himmer, Reichenbach (DE)

(21) Appl. No.: 15/489,472

(22) Filed: Apr. 17, 2017

(30) Foreign Application Priority Data
Apr. 18, 2016 (DE) DE102016206506.8

(51) Int. Cl. H01L 35/32

(52) U.S. Cl. CPC H01L 35/32

(57) ABSTRACT

A thermoelectric module may include a plurality of thermoelectric elements arranged spaced apart from one another between a hot-side substrate and a cold-side substrate. A plurality of conductor bridges may electrically interconnect the plurality of thermoelectric elements and may contact at least one electric connection. The at least one electric connection may include a contact element that is pre-stressed via a pre-stressing arrangement and lies against at least one conductor bridge of the plurality of conductor bridges.

### CROSS-REFERENCE TO RELATED APPLICATION

This application claims priority to DE 10 2016 206 506.8 filed on Apr. 18, 2016, the contents of which are hereby incorporated by reference in its entirety.

### TECHNICAL FIELD

The present invention relates to a thermoelectric module.

### BACKGROUND

A generic thermoelectric module is known for example from DE 10 2013 214 988 A1 or from EP 2 159 854 A1. Such a module comprises a plurality of thermoelectric elements which are arranged spaced apart from one another between a hot side of the module and a cold side of the module. In addition, a plurality of conductor bridges are provided for the electrical interconnecting of the thermoelectric elements and for contacting with electric connections of the module. A hot-side substrate, forming the hot side, consists of an electrically insulating material or has an electrical insulation on an inner side facing the thermoelectric elements. In an analogous manner thereto, a cold-side substrate forms the cold side and consists of an electrically insulating material or has an electrical insulation on an inner side facing the thermoelectric elements. In the thermoelectric module known from EP 2 159 854 A1, in addition an electrically insulating mount is known for positioning the thermoelectric elements between the substrates, wherein the mount has a separate through-opening for each thermoelectric element, into which the respective thermoelectric element is inserted.

Thermoelectric elements consist of thermoelectric semiconductor materials, which convert a temperature difference into a potential difference, therefore into an electric voltage, and vice versa. In this way, a heat flow can be converted into an electric current and vice versa. The thermoelectric modules are based on the Peltier effect when they convert electrical energy into heat, and on the Seebeck effect when they convert heat into electrical energy. Within a thermoelectric module, p-doped and n-doped thermoelectric elements are interconnected with one another. Usually, several such thermoelectric modules are connected together to a thermoelectric generator, which can be used according to current feed for cooling or for heating, or which can generate an electric current from a temperature difference in connection with a corresponding heat flow.

For example, such thermoelectric modules or respectively thermoelectric generators can come into use for waste heat recovery in internal combustion engines, in particular in motor vehicles, for example in order to convert waste heat contained in the exhaust gas into electrical energy. A problem in such applications are the temperatures, varying in a large temperature range, in connection with the requirement that as efficient a heat transmission as possible is desired within the thermoelectric module between the thermoelectric elements and the substrates, whilst at the same time at this location an electrical insulation must be present. Materials which have good thermal conductivity generally have a poor electrical insulation. In addition, materials which insulate well thermally, generally have a poor electrical conductivity. Furthermore, the varying temperatures can lead to thermally-caused expansion effects, which result in relative movements of the individual components within the thermoelectric module. Such relative movements can increase the mechanical load of the thermoelectric module. Such thermomechanical loads impair the lifespan of such a thermoelectric module. The thermomechanical loads occur here on the one hand between the thermoelectric elements and the conductor bridges and on the other hand between the conductor bridges and the substrates. In addition, such thermomechanical loads also occur between electric contacts and the conductor bridges connected therewith.

### SUMMARY

The present invention is concerned with the problem of indicating for a thermoelectric module of the type described above an improved or at least a different embodiment, which is distinguished by a reduced thermomechanical load.

This problem is solved according to the invention in particular by the features of the independent claim. Advantageous embodiments are the subject of the dependent claims. Further solutions and further advantageous embodiments are also to be found in the following description.

According to a first aspect, the present invention is based on the idea of equipping the conductor bridges respectively with a bridge body which is configured so as to be thermally and electrically conductive and able to be deformed elastically. Through the electrical conductivity of this bridge body, the thermoelectric elements associated with the respective conductor bridge can be connected electrically to one another. Through the thermal conductivity of the bridge body, the heat flow between the thermoelectric elements, associated with the conductor bridge, and the associated substrate can be improved. The elastic deformability of the bridge body can compensate thermally-caused relative movements between the thermoelectric elements and the substrates and can therefore reduce the thermomechanical loads. As, consequently, the thermomechanical loads within the bridge body are largely compensated, the bridge body, and therefore the conductor bridge equipped therewith, brings about a thermomechanical decoupling between the associated thermoelectric elements and the associated substrate. In this respect, the lifespan of the thermoelectric module can be improved.

Conductor bridges which are equipped with such a bridge body can be arranged between the thermoelectric elements and the hot-side substrate. Likewise, the conductor bridges which are equipped with such a bridge body can be arranged between the thermoelectric elements and the cold-side substrate. Preferably, all the conductor bridges associated with the hot-side substrate and/or all the conductor bridges associated with the cold-side substrate are equipped respectively with such a bridge body.

According to an advantageous embodiment, the respective conductor bridge can have on its inner side, facing the thermoelectric elements, a metallic conducting body, which is arranged outside the bridge body between the two thermoelectric elements which are electrically connected to one another by this conductor bridge. It has been found that by means of such a conducting body, the electric resistance of the bridge body can be significantly reduced. Accordingly, the electrical conductivity of the conductor bridge improves, which improves the energetic efficiency of the thermoelectric module.

According to a further development, the respective conducting body can be electrically connected to the bridge body, which improves the effect described above.

Furthermore, the respective conducting body can be arranged spaced apart from the two thermoelectric elements which are electrically connected to one another by the respective conductor bridge. The respective conducting body therefore does not bring about a short-circuit for bypassing the bridge body and therefore does not bring about any direct electric connection between the thermoelectric elements concerned. Rather, only the electrical conductivity of the bridge body is improved by the conductor body.

Additionally or alternatively, the respective conducting body can extend exclusively between the two thermoelectric elements along the bridge body. Therefore, the respective conducting body is comparatively small and, accordingly, economically priced. Preferably, the respective conducting body can extend over the entire width of the bridge body, wherein the conducting body extends, in addition, transversely to the longitudinal direction of the bridge body.

According to another advantageous embodiment, the respective bridge body can be formed by graphite foil. Graphite foil is distinguished by a comparatively good electrical conductivity on the one hand, and by a comparatively good thermal conductivity on the other hand. Particularly advantageous, however, in graphite foil, is its elastic deformability.

Alternatively thereto, the respective bridge body can be formed by a porous metal structure. Metals are generally good electrical and thermal conductors. Through the porosity of the metal structure, its elastic deformability is significantly increased. Examples of porous metal structures are, for example, metal braiding, metal pads, metal mesh, metal foam, metal textile or knitted wire mesh, and any desired combinations of at least two such structures. Therefore, a bridge body can be provided comparatively simply and at an economical price, which bridge body has a comparatively high thermal and electrical conductivity and furthermore is elastically deformable to a comparatively high extent.

In an advantageous embodiment, the respective conductor bridge, having the bridge body, can lie loosely against the respective substrate. In other words, in this embodiment, a fixed connection between conductor bridge and substrate is dispensed with. This provision facilitates relative movements between the conductor bridge and the respective substrate and reduces the risk of thermally induced mechanical stresses.

According to a further development, the respective bridge body can lie loosely directly against the respective substrate. Here, the bridge body can lie against the inner side of the substrate or respectively against the electrical insulation which is provided there if applicable, which insulation belongs to the coverage of the substrate.

In another embodiment, the respective bridge body can have a metal coating on an inner side facing the thermoelectric elements, which metal coating is mechanically connected securely, in particular in a materially bonded manner, to the two thermoelectric elements which are electrically connected by the respective conductor bridge. Through the metal coating, together with the fixed mechanical connection, the electrical contacting between the associated thermoelectric elements can be improved.

Alternatively thereto, it is also possible to equip at least one of the substrates with a metal layer on its inner side, wherein the respective bridge body has, on an outer side facing the respective substrate, a metal coating which is mechanically connected securely, in particular in a materially bonded manner, to the metal layer of the respective substrate. Such a fixed connection improves the transmission of heat between conductor bridge and substrate.

In another embodiment, the respective conductor bridge can have a metal bridge on an inner side of the bridge body facing the thermoelectric elements, which metal bridge is arranged between face sides, facing the bridge body and the respective substrate, of the two thermoelectric elements electrically connected to one another by the conductor bridge. In such an embodiment, the electrical conductor function of the conductor bridge is largely fulfilled by the metal bridge, whilst the bridge body continues to fulfil the function of the thermomechanical decoupling. In this case, the bridge body itself does not obligatorily have to be electrically conductive.

In a further development, the respective metal bridge can be mechanically connected securely, in particular in a materially bonded manner, to the face sides of the two thermoelectric elements. This secure connection improves, on the one hand, the transmission of heat, and on the other hand also the electrical contacting.

In another embodiment, the respective metal bridge can be supported on the respective face side by means of at least one further thermally and electrically conductive and elastically deformable bridge body. In this respect, a sandwich structure is proposed here, in which the metal bridge is arranged between at least two bridge bodies. Basically, a common further bridge body can be provided, which extends from the one thermoelectric element to the other thermoelectric element. Alternatively thereto, two separate further bridge bodies can be provided, so that the one further bridge body is associated with the one thermoelectric element, whilst the other further bridge body is associated with the other thermoelectric element. Between these two further bridge bodies, a gap expediently extends, which is configured continuously up to the metal bridge.

According to a further development, the at least one further bridge body can lie loosely against the respective face side or can have a metal coating and can be mechanically connected securely, in particular in a materially bonded manner, to the respective face side. Additionally or alternatively, the at least one further bridge body can lie loosely against the metal bridge or can have a metal coating and can be mechanically connected securely, in particular in a materially bonded manner, to the metal bridge.

In addition, the actual bridge body can lie loosely against the metal bridge, or can have a metal coating and can be securely connected, in particular in a materially bonded manner, to the metal bridge.

A second aspect of the present invention proceeds from a thermoelectric module which is configured with a mount for positioning the thermoelectric elements between the substrates. This mount is configured so as to be electrically insulated; for example, it is produced from at least one electrically insulating material, such as e.g. plastic or ceramic. This mount can come into use particularly advantageously with the above-mentioned bridge bodies, which enable a thermomechanical decoupling between the respective conductor bridge and the respective substrate, that the mount positions the thermoelectric elements relative to one another. According to a first sub-aspect of this second aspect, it is now proposed to loosely apply the conductor bridges, proximal to the hot-side substrate, therefore the conductor bridges associated with the hot-side substrate, against the hot-side substrate. Additionally or alternatively, it is proposed to loosely apply the conductor bridges proximal to the cold-side substrate, therefore the conductor bridges associated with the cold-side substrate, loosely against the cold-side substrate. The loose abutment of the conductor bridges against the associated substrate enables relative movements between the conductor bridges and the respective substrate, whereby thermally caused stresses between conductor bridges and substrate are reduced. In connection with the mount, a desired relative position between the thermoelectric elements can continue to be guaranteed here, so that the thermoelectric elements can move, as it were, as a cohesive block, relative to the respective substrate.

According to a second sub-aspect of the second aspect, which can be realized additionally or alternatively to the first sub-aspect described above, it is proposed to equip the mount with a hot region of a first material, facing the hot-side substrate, and with a cold region of a second material different from the first material, facing the cold-side substrate. Hereby, the mount is not a homogeneous component of a single material, but rather a hybrid component which has at least two regions of different materials. Hereby, the mount can be optimized with regard to the thermal loads which occur within the thermoelectric module. For example, the first material of the hot region, which is situated proximally to the hot side of the module, has a higher thermal stability than the second material of the cold region, which is arranged proximally to the cold side of the module. In particular, the temperature range, in which such a thermoelectric module can be used, can thereby also be increased towards higher temperatures.

In particular according to a further development, provision can be made that the hot region is produced from ceramic, whereas the cold region is produced from plastic. The ceramic hot region thereby receives a very high thermal stability, whilst the cold region, produced from plastic, reduces the production costs of the mount.

In another further development, the mount can have a first mount portion, which forms the holding region, and a second holding portion, which forms the cold region, which are fitted against one another. The two holding portions are therefore produced separately and are subsequently assembled, in order to form the mount. Alternatively, it is likewise conceivable to firstly produce the one holding portion, in order to then produce the other holding portion thereon by casting on or injecting on.

In another further development, provision can be made that the through-openings for the inserting of the thermoelectric elements are formed only on the hot region or only on the cold region. This provision also reduces the production costs for the mount. The respective other region can then be configured e.g. as a frame which encompasses the thermoelectric elements.

According to a third sub-aspect of the second aspect, which can be realized additionally or alternatively to the above-mentioned sub-aspects, it is proposed that the mount for the conductor bridges proximal to the hot-side substrate and/or for the conductor bridges proximal to the cold-side substrate has recesses, into which the conductor bridges are inserted, so that a recessed arrangement results for the conductor bridges in the mount. Therefore, through the mount, not only a positioning of the thermoelectric elements, but also a positioning of the conductor bridges takes place. This simplifies the production and handling of a unit of mount, thermoelectric elements and conductor bridge.

Basically, the recesses can be dimensioned so that the conductor bridges can be only partially inserted therein. Consequently, the mount has a distance from the hot-side substrate and/or from the cold-side substrate. The distance reduces interactions between the mount and the substrate. In particular, the heat conduction is thereby reduced through the mount and instead is concentrated on the thermoelectric elements.

Alternatively, it is likewise possible to arrange the conductor bridges recessed so far in the recesses that they terminate flush with an outer side of the mount facing the respective substrate. Consequently, the respective outer side of the mount lies directly against the facing substrate. This provision can simplify the installation of the module and gives the module an increased stability.

According to a fourth sub-aspect of the second aspect, which can be realized additionally or alternatively to the above-mentioned sub-aspects, it is proposed that the mount has a hot part, proximal to the hot-side substrate, and a cold part, proximal to the cold-side substrate, wherein the through-openings are formed both in the hot part and also in the cold part. Through this provision, the positioning function of the mount is improved.

According to a further development, the hot part can be fastened to the hot-side substrate, whereas the cold part is arranged adjustably relative to the hot part along the thermoelectric elements. Alternatively, provision can also be made that the cold part is fastened to the cold-side substrate, whereas the hot part is arranged adjustably relative to the cold part along the thermoelectric elements. In other words, according to this embodiment the one mount portion is fastened to the associated substrate, whereas the other mount portion is adjustable relative to the substrates along the thermoelectric elements. This type of construction has advantages as regards installation. For example, for pre-assembling, a comparatively great distance can be set between the mount portions, in order to be able to reliably position relative to one another the thermoelectric elements which are used. After the fixing of the one holding portion on the associated substrate, this distance between the mount portions can be reduced, so that the mount, after installation of the other substrate, has a (greater) distance hereto.

According to a further development, provision can be made that the hot part and the cold part are arranged adjustably to one another via a guide. Alternatively, provision can be made that the holding portion, the hot part and the cold part are fastened to one another via an articulated and/or elastic connection, which permits the relative adjustment. Likewise, a rigid connection can be provided, which contains a predetermined breaking point, in order to enable the relative adjustment when the connection is broken. These provisions also facilitate the installation of the module.

In another embodiment, an intermediate space can be formed in the region of the thermoelectric elements between the hot part and the cold part, in which intermediate space the hot part and cold part are spaced apart from one another. Hereby, the mount has comparatively little volume, which reduces the material usage and therefore the production costs. The heat conduction between the substrates is also reduced through the mount and instead is concentrated on the thermoelectric elements.

According to a fifth sub-aspect of the second aspect, which can be realized additionally or alternatively to the sub-aspects described above, provision is made that the mount has a positioning region having the through-openings, which positioning region is supported via holding regions on at least one of the substrates. Furthermore, provision is made that this positioning region has a greater distance from the hot-side substrate than from the cold-side substrate. In this way, the thermal load of the positioning region, and therefore of the mount, is significantly reduced.

According to a further development, the respective holding region can be clipped or screwed or pinned or glued to the respective substrate. Owing to the different temperatures on the hot-side substrate on the one hand and on the cold-side substrate on the other hand, different fastening techniques can also come into use. For example, the respective holding region is clipped or screwed to the hot-side substrate, whereas it is pinned or glued to the cold-side substrate.

According to a third aspect of the present invention, which is able to be realized additionally or alternatively to the above-mentioned first aspect and/or to the above-mentioned second aspect, it is proposed that at least one such electrical connection of the module is equipped with a contact element which lies, pre-stressed by means of a pre-stressing arrangement, against such a conductor bridge. Whereas usually a materially bonded connection between a contact element of the electrical connection and the respective conductor bridge is preferred, a pre-stressed abutment also enables a materially-bonded connection to be dispensed with and consequently enables also for the conductor bridge the use of materials in which a materially bonded connection is not, or is not readily, possible. By means of the pre-stressing arrangement, the desired pre-stressed abutment of the contact element against the respective conductor bridge can be realized. Hereby, a sufficient electrical contacting is guaranteed, which furthermore can react elastically to thermally-caused relative movements. The pre-stressing arrangement is oriented here expediently parallel to a distance direction between the substrates. Consequently, the contact element lies against an inner side of the conductor bridge, which faces away form the substrate with which this conductor bridge is associated, and against which this conductor bridge, in turn, lies. Therefore, the conductor bridge, the contact element and the associated substrate form a sandwich structure, in which the respective substrate and the contact element lie on the outside, whereas the conductor bridge is arranged lying inside.

An embodiment is advantageous, in which the pre-stressing arrangement pre-stresses the contact element in the direction of the one substrate against the respective conductor bridge, and in so doing rests against the other substrate. The pre-stressing force of the pre-stressing arrangement represents an action which according to the basic principles of physics requires a corresponding reaction, namely an oppositely oriented supporting force. According to this proposal, this supporting force is accordingly supported on the opposite substrate. Therefore, a closed force path is formed within the thermoelectric module.

In an advantageous further development, the pre-stressing arrangement can rest against the other substrate parallel to a distance direction of the substrates aligned to the contact element. Hereby, the pre-stressing arrangement is extremely compact in construction.

In another further development, the pre-stressing arrangement can have a support element, which is supported on the other substrate. Hereby, the force transmission between the pre-stressing arrangement and the other substrate is improved.

In a further development, this support element can be guided in a longitudinally adjustable manner on the contact element. Therefore, the support element and contact element are positioned with respect to one another, which improves the generation of the pre-stressing force.

The support element and contact element can be inserted into one another for the formation of a telescopic guide. Hereby, a particularly efficient longitudinal guide is realized between the elements of the pre-stressing arrangement with reciprocal centering.

Advantageously, the pre-stressing arrangement can have a spring element, which rests on the one hand against the support element and on the other hand against the contact element. Therefore, the spring element is situated between the substrates and therefore in particular within the module. Hereby, the pre-stressing arrangement is given a particularly compact structural form.

Advantageously, provision can now be made that the spring element is arranged centrically to a straight connection line, which extends parallel to the distance direction of the substrates and which leads directly from a contact point, via which the contact element lies against the respective conductor bridge, to a support point, via which the support element rests against the respective substrate. This also brings about an extremely compact embodiment for the pre-stressing arrangement.

A further development is particularly expedient, in which the spring element is arranged in the telescopic guide. This embodiment is also distinguished by an extremely compact type of construction.

Alternatively thereto, the pre-stressing arrangement can have a contact lever, having the contact element, and a support lever, having the support element, which are mounted swivellably to one another about a swivel axis running perpendicularly to the distance direction of the substrates. The equipping of the pre-stressing arrangement with such levers makes it possible to direct the levers out of the region of the substrates and therefore out of an interior of the module. Usually, more installation space is available outside the module, for example in order to generate the pre-stressing force.

According to an advantageous further development, the pre-stressing arrangement can have a spring element which is supported in a pre-stressed manner on the contact lever and on the support lever on a side of the swivel axis facing away form the contact element and from the support element. This spring element is therefore situated expediently outside the substrates and in particular outside an interior of the module. Hereby, in particular, a greater and/or stronger spring element can be used.

In another further development, preferably the contact lever or the support lever can have at en end remote from the contact element and from the support element a connection point for the connecting of an electric cable. By means of the levers, therefore, this connection point can likewise be arranged outside the substrates or respectively outside an interior of the module, which simplifies the installation of the module.

Whereas the contact element and, if applicable, the contact lever, are produced from an electrically conductive material, e.g. metal, the support element and, if applicable, the support lever, can be produced from an electrically insulating material, e.g. plastic.

According to an advantageous further development, the support element can have, on an outer side facing away from the one substrate, a projecting pin, which engages into a pin mount formed on the other substrate. Hereby, a secure fixing in position is realized for the support element on the other substrate.

The contact element can be equipped, on an outer side facing the conductor bridge, with a contact contour which has a plurality of linear and/or punctiform contact zones for contacting with the conductor bridge. For example, the contact contour can have a plurality of webs tapering towards the conductor bridge and/or a plurality of tapering pyramid-like or cone-like projections. Through the pre-stressing force, the contact contour can penetrate more or less deeply into the conductor bridge, depending on the material of the conductor bridge. This can considerably improve the electrical contacting.

Irrespective of whether the first, second or third aspect of the invention is concerned, the module can have a housing which contains a hermetically closed interior, in which the thermoelectric elements are arranged. Hereby, the thermoelectric elements in the interior are protected from harmful environmental influences, for example from impurities and moisture. The interior can be evacuated or can be filled with a protective gas. Alternatively thereto, it is basically possible, again irrespective of whether the first, second or third aspect of the invention is concerned, that the hot-side substrate is a component of a wall of a heating channel for directing a heating fluid, wherein additionally or alternatively provision can be made that the cold-side substrate is a component of a wall of a cooling channel for directing a cooling fluid. Through the integration of the respective substrate into the wall of such a channel, the heat transmission between the substrate and the respective fluid improves, because a direct contacting of the respective fluid with the respective substrate takes place.

Likewise irrespective of the respective aspect of the present invention and of the associated embodiments and their combinations, the respective hot-side substrate and/or the respective cold-side substrate can consist of an electrically insulating material or can have an electrical insulation on an inner side facing the thermoelectric elements.

In all the mentioned aspects, the respective thermoelectric module is expediently configured as a flat, plate-shaped body. Accordingly, the substrates are likewise plate-shaped bodies, which extend respectively in a plane. Alternatively thereto, it is basically possible to configure such a thermoelectric module cylindrically or in the shape of a cylinder segment, so that the substrates have corresponding curved shapes.

Further important features and advantages of the invention will emerge from the subclaims, from the drawings and from the associated figure description with the aid of the drawings.

It shall be understood that the features mentioned above and to be explained further below are able to be used not only in the respectively indicated combination, but also in other combinations or in isolation, without departing from the scope of the present invention. The present disclosure therefore comprises in particular also all combinations which can result through any desired combining of the three named aspects and their sub-aspects and their embodiments and further developments.

Preferred example embodiments of the invention are illustrated in the drawings and are explained further in the following description, wherein the same reference numbers refer to identical or similar or functionally identical components.

### BRIEF DESCRIPTION OF THE DRAWINGS

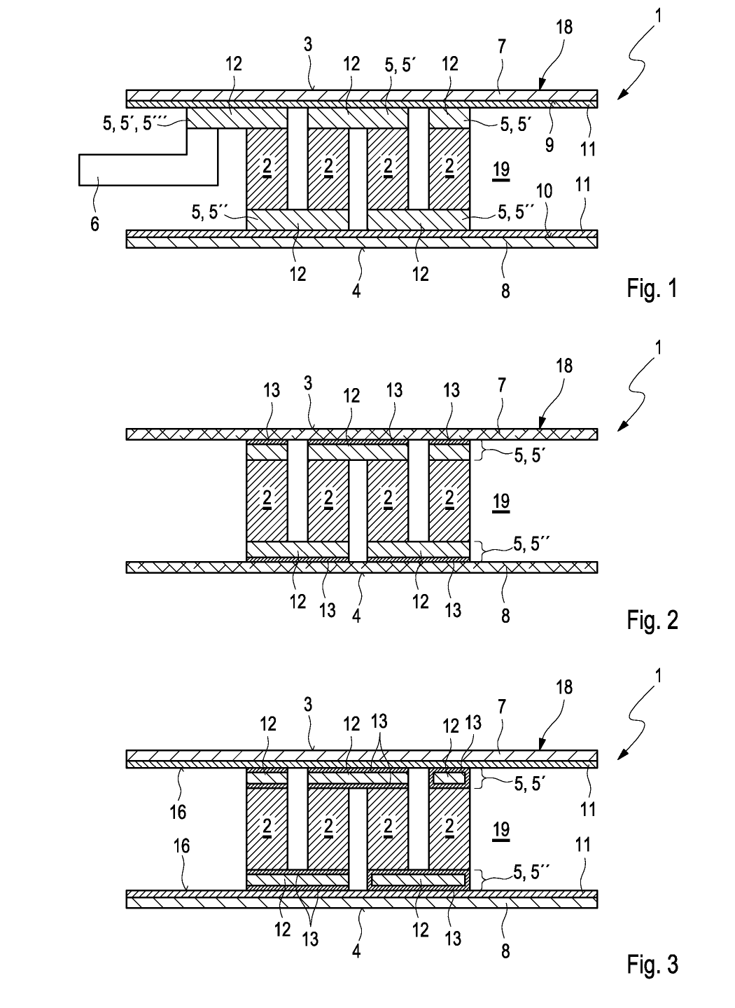

There are shown, respectively diagrammatically, FIGS. 1 to 18 respectively a highly simplified sectional view of a thermoelectric module in different embodiments.

### DETAILED DESCRIPTION

The different embodiments described below with the aid of FIGS. 1 to 18 are basically able to be combined with one another as desired, in so far as this is expedient. In addition, the embodiments belong to three basic aspects of the present invention, which can likewise be combined with one another as desired, in so far as this is expedient. The second of these aspects has several sub-aspects, which likewise are able to be combined with one another as desired, in so far as this is expedient.

According to FIGS. 1 to 18, a thermoelectric module 1 comprises a plurality of thermoelectric elements 2. In the illustrations, precisely four such thermoelectric elements 2 are shown, purely by way of example. It is clear that such a module 1 can basically have any desired number of such thermoelectric elements 2, which are preferably arranged at least two-dimensionally, therefore not only along the plane of the drawing, but also perpendicularly thereto. The thermoelectric elements 2 are arranged spaced apart from one another between a hot side 3 of the module 1 and a cold side 4 of the module 1. Furthermore, the module 1 has a plurality of conductor bridges 5, which serve for the electrical interconnecting of the thermoelectric elements 2 and for the connecting of electrical connections 6, of which per module 1 at least two are present, of which, however, respectively only one is illustrated in FIGS. 1 and 16 to 18. The conductor bridges 5 associated with or respectively facing the hot side 3 can also be designated in the following by 5′. The conductor bridges 5 associated with or respectively facing the cold side 4 can also be designated in the following by 5″. The conductor bridge 5 provided for connecting an electrical connection 6 can also be designated in the following by 5′″.

The hot side 3 is formed by a hot-side substrate 7. The cold side 4 is formed by a cold-side substrate 8. In the example of FIG. 2 the two substrates 7, 8 are produced respectively from an electrically insulating material, such as for example from a ceramic. In all other embodiments, the substrates 7, 8 are produced from an electrically conductive material, preferably from a metal, in particular high-grade steel, and on their inner side 9 or respectively 10 facing the thermoelectric elements 2, they are equipped with an electrical insulation 11, which forms a component of the respective substrate 7, 8.

The conductor bridges 5 can basically be produced from any desired electrically and thermally conductive material. According to a first aspect of the present invention, at least the conductor bridges 5 associated with one of the substrates 7, 8 have respectively a bridge body 12, which is configured so as to be thermally and electrically conductive and elastically deformable. Expediently, both the conductor bridges 5′, which as associated with the hot side 13, and also the conductor bridges 5″, which are associated with the cold side 4, are respectively equipped with such a bridge body 12.

According to FIG. 1, the bridge bodies 12 can lie directly against the respective substrate 7, 8, in particular against its insulation 11. In the example of FIG. 2, the bridge bodies 12 rest respectively via a metal coating 13 against the respective substrate 7, 8. The metal coating 13 can be formed here on the respective bridge body 12 or on the respective substrate 7, 8.

In the example of FIG. 3, the respective conductor bridge 5 has on the associated bridge body 12 both on an outer side facing the respective substrate 7, 8 and also on an inner side facing the respective thermoelectric element 2 respectively a metal coating 13. In addition, in FIG. 3, it is indicated at the two bridge bodies 12 arranged on the right that the respective metal layer 13 can also be configured so as to be circumferential, so that ultimately the entire surface of the bridge body 12 is formed by the metal layer 13.

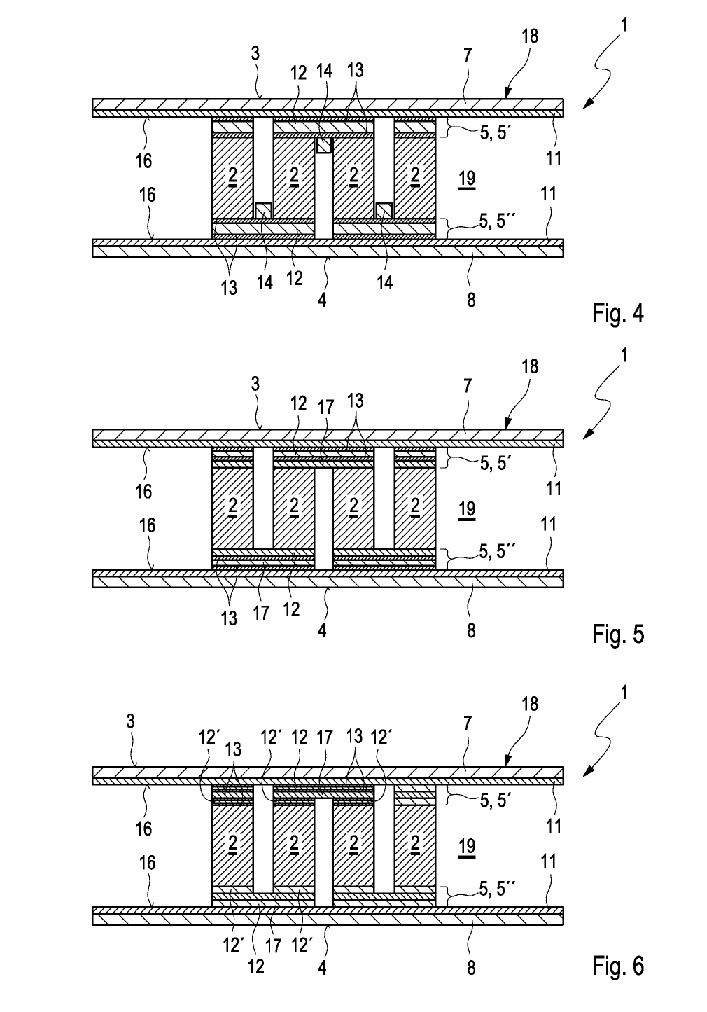

According to FIG. 4, the respective conductor bridge 5 can have a metallic conducting body 14 on its inner side facing the thermoelectric elements 2. The conducting body 14, for example a piece of wire, which has here expediently a rectangular cross-section, is arranged here outside the bridge body 12 between the two thermoelectric elements 2, which are electrically connected to one another by the respective conductor bridge 5. The respective conducting body 14 is electrically connected to the respective bridge body 12. In the example of FIG. 4, this takes place by a contacting of the conducting body 14 with the metal layer 13. In particular, the conducting body 14 can be connected, preferably in a materially bonded manner, to the metal layer 13. Primarily, a soldered connection is conceivable. In the example of FIG. 4, the respective conducting body 14 is arranged spaced apart from the two thermoelectric elements 2, which are electrically connected to one another by the respective conductor bridge 5. In FIG. 4, corresponding clearances or gaps can be seen, which are not designated in further detail. Expediently, the respective conducting body 14 extends only between these two thermoelectric elements 2, which are electrically connected to one another by the associated conductor bridge 5, along the associated bridge body 12. Preferably, the respective conducting body 14 extends here only over the entire width of the bridge body 12 and is oriented here transversely to the longitudinal direction of the bridge body 12. In the sectional views shown here, the straight-lined conducting bodies 14 extend with their longitudinal extent perpendicularly to the plane of the drawing. The longitudinal direction of the associated bridge bodies 12 lies in the plane of the drawing.

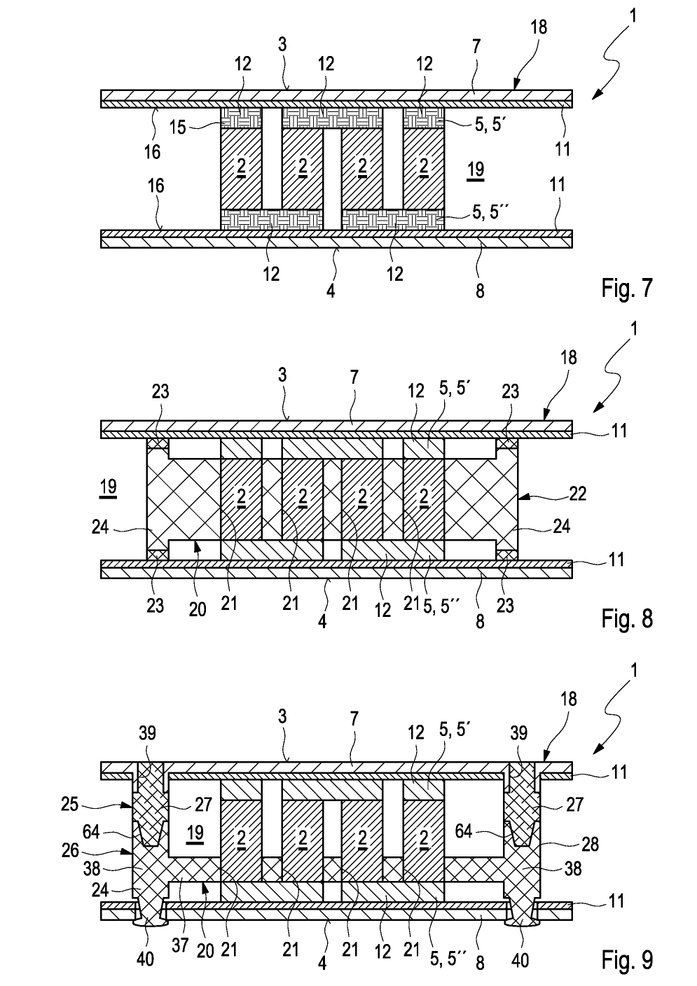

The bridge body 12 is expediently formed by a graphite film, which can be the case for example in the embodiments of FIGS. 1 to 6 and 8 to 18. Purely by way of example, in FIG. 7 a different embodiment is indicated, in which the respective bridge body 12 is formed by a porous metal structure 15. It is clear that basically also in the other embodiments the bridge body 12 can be formed by such a metal structure 15. The porous metal structure 15 is formed here expediently by a member of the group of metal braiding, metal pads, metal mesh, knitted wire mesh, metal foam, metal textile or of any desired combination of two or more members of this group.

In so far as the respective bridge body 12 according to FIGS. 3 and 4 has the metal coating 13 on its inner side facing the thermoelectric elements 2, the bridge body 12 can be securely connected via the metal coating 13, preferably in a materially bonded manner, to the respective thermoelectric elements 2.

Irrespective of whether or not such a metal coating 13 is present, provision can be made according to another embodiment that the respective conductor bridge 5, equipped with the bridge body 12 and in an extreme case formed by the bridge body 12, lies loosely against the respective substrate 7, 8. In particular here the respective bridge body 12 can lie loosely directly against the respective substrate 7, 8. In particular, the respective bridge body 12 here can lie loosely directly against the respective substrate 7, 8. Such a direct contacting is shown in FIG. 1. There, the bridge body 12 in fact lies against the respective insulation 11, but this forms a component of the respective substrate 7, 8.

In contrast, in so far as a secure fixing between the respective conductor bridge 5 and the respective substrate 7, 8 is desired, this can be realized for example by the metal coating 13 on the bridge body 12, which is formed for this at least on an outer side of the bridge body 12 facing the respective substrate 7, 8. Expediently, the insulation 11 of the respective substrate 7, 8 can then also be metallized or can be provided with a metal layer, which is indicated purely by way of example only in FIGS. 3 to 7 and is designated by 16. Therefore, a materially bonded connection, preferably a soldered connection, can also be realized here. The same applies to the embodiment shown in FIG. 7, in which the porous metal structure 15 can be securely connected directly to the metal layer 16 of the insulation 11.

In the examples of FIGS. 5 and 6, the respective conductor bridge 5 is equipped furthermore with a metal bridge 17, which is provided in addition to the bridge body 12 and which is situated here on an inner side of the respective bridge body 12 facing the thermoelectric elements 2. The metal bridge 17 extends expediently over the entire length of the associated bridge body 12 and is therefore ultimately arranged between the bridge body 12 and axial face sides of the two thermoelectric elements 2, with which the respective bridge body 12 or respectively the respective conductor bridge 5 is associated. The said face sides of the thermoelectric elements 2 are facing the respective substrate 7, 8. In the example of FIG. 5, the respective metal bridge 17, which of course consists of a metallic material, is directly in contact with the face sides of the two thermoelectric elements 2. Expediently, a secure, preferably materially bonded, connection is also preferred here.

In contrast thereto, FIG. 6 shows an embodiment in which the respective metal bridge 17 is supported on the respective face side via at least one further bridge body 12′, which is likewise configured so as to be thermally and electrically conductive and elastically deformable. In the example of FIG. 6, two separate further bridge bodies 12′ are provided here per metal bridge 17. Basically, however, a common, continuous further bridge body 12′ is conceivable. In FIG. 6, in the case of the conductor bridges 5″, which are associated with the cold-side substrate 8, provision is made that the bridge body 12 lies directly′ against the cold-side substrate 8 and directly against the metal bridge 17. Furthermore, provision is made there that the further bridge bodies 12′ on the one hand lie respectively directly against the thermoelectric elements 2 and on the other hand against the metal bridge 17. Depending on the material of the bridge body 12 or respectively of the further bridge body 12′, a loose abutment or a, preferably materially bonded, fixing comes into consideration here. In FIG. 6, in the case of the three left-hand thermoelectric elements 2, provision is made that the conductor bridges 5′ associated with the hot-side substrate 7′, are still configured so that the associated bridge bodies 12 and also the further bridge bodies 12′ are equipped respectively with the metal coating 13 on their outer side facing the hot-side substrate 7, and also with the metal coating 13 on their inner side facing the cold-side substrate 8. Therefore, in particular an embodiment is possible in which the bridge body 12 is fastened via the metal coating 13, and the further metal layer 16, provided if applicable on the insulation 11, on the hot-side substrate 7. Furthermore, these bridge bodies 12 are also fastened on the metal bridge 17 via the metal coating 13. The further bridge bodies 12′ are fastened here on the one hand on the respective thermoelectric element 2 and on the other hand on the respective metal bridge 17 respectively via the metal coating 13.

Expediently the module 1 has, moreover, a housing 18, which is only partially illustrated in FIGS. 1 to 18 and which contains an interior 19 which is hermetically closed to the exterior. The thermoelectric elements 2 are arranged in this interior 19. Expediently, two walls of the housing 19, facing away from one another or respectively remote from one another, are formed by the substrates 7, 8. In an alternative type of construction, the hot-side substrate 7 can form a component of a wall of a heating channel, in which a heating fluid is directed. Additionally or alternatively, the cold-side substrate 8 can form a component of a wall of a cooling channel, in which a coolant is directed. Hereby, the modules 1 can be integrated into a heat exchanger in a particularly simple manner.

According to FIGS. 8 to 15, according to a second aspect of the present invention, the module 1 can have, furthermore, an electrically insulating mount 20, which serves for the positioning of the thermoelectric elements 2 between the substrates 7, 8. Such a mount 20 can basically be provided in all the embodiments which are shown here. In so far as a housing 18 is present, the mount 20 is arranged in the interior 19. The mount 20 has a separate through-opening 21 for each thermoelectric element 2, into which through-opening the respective thermoelectric element 2 is inserted. Expediently, an internal cross-section of the respective through-opening 21 is coordinated with an external cross-section of the respective thermoelectric element 2 so that a secure fixing in position occurs for the respective thermoelectric element 2 in the through-opening 21 on the mount 20.

Such a mount 20 can come into use for example when the conductor bridges 5′, proximal to the hot-side substrate 7, lie loosely against the hot-side substrate 7 or respectively against its insulation 11 and/or when the conductor bridges 5″, proximal to the cold-side substrate 8, lie loosely against the cold-side substrate 8 or respectively against its insulation 11. This corresponds to a first sub-aspect of this second aspect of the invention. In particular, thereby a block designated by 22 in FIG. 8, can be created, which is mounted as it were in a floating manner between the substrates 7, 8. Alternatively thereto, the mount 20 itself can be securely connected via suitable connection points 23 to the hot-side substrate 7 and/or to the cold-side substrate 8. For example, the mount 20 is fastened to the respective substrate 7, 8 only in a circumferential region 24, which surrounds the thermoelectric elements 2 in the circumferential direction.

FIG. 9 shows a second sub-aspect of this second aspect of the invention. For this, provision is made that the mount 20 has a hot region 25 facing the hot-side substrate 7, and a cold region 26 facing the cold-side substrate 8, which are produced from different materials. Accordingly, the hot region 25 is produced from a first material, which can be, for example, a ceramic. In contrast thereto, the cold region 26 is produced from a second material, which is different from the first material, and which can be, for example, a plastic. In the example of FIG. 9, the hot region 25 is formed by at least a first mount portion 27, whilst the cold region 26 is formed by at least a second mount portion 28. The different holding parts 27, 28 are fitted against one another. In the example of FIG. 9, a plug connection 64 is formed between the two mount portions 27, 28, which plug connection has cone-shaped or wedge-shaped projections on the first mount portion 27, and cone-shaped or wedge-shaped depressions, complementary thereto, on the second mount portion 28. The first mount portion 27 and second mount portion 28 are configured in FIG. 9 so that the above-mentioned through-openings 21 are formed exclusively on the second mount portion 28 or respectively on the hot region 26.

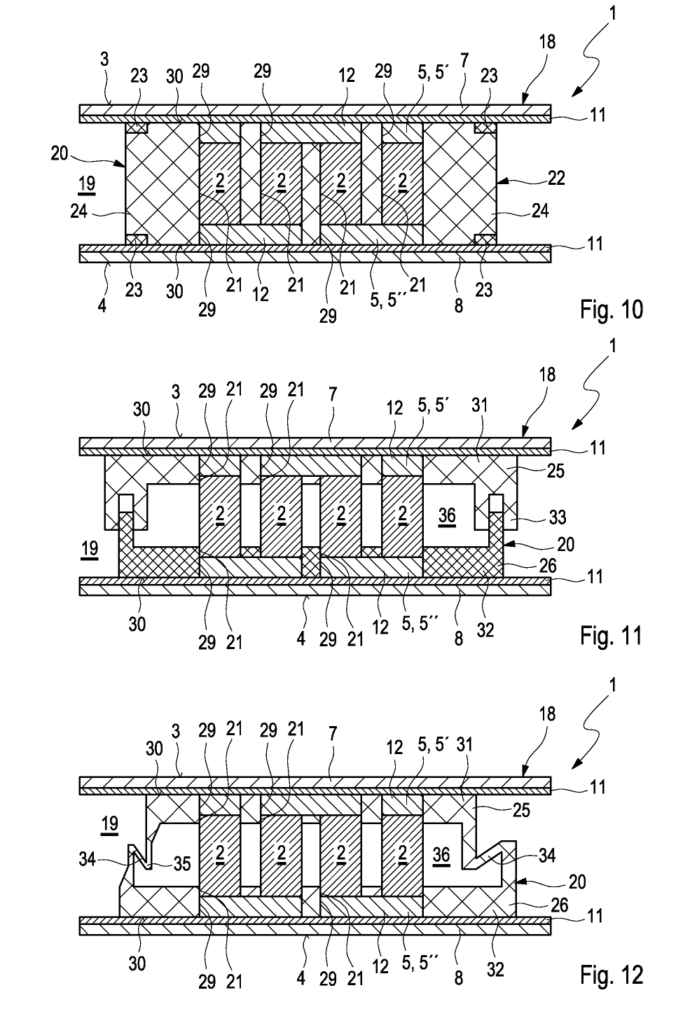

FIG. 10 shows a third sub-aspect of the second aspect of the present invention. Here, the mount 20 for the conductor bridges 5′ proximal to the hot-side substrate 7, and/or for the conductor bridges 5″ proximally to the cold-side substrate 8, has respectively a recess 29, in which the conductor bridges 5 are arranged in a recessed manner. A specific embodiment is shown here, in which the recesses 29 are dimensioned so that the conductor bridges 5 are arranged therein in a recessed manner to such an extent that they respectively terminate in a flush manner with an outer side 30 of the mount 20 facing the respective substrate 7, 8. Hereby, said outer side 30 lies flat against the respective substrate 7, 8.

According to FIGS. 11 and 12, in accordance with a fourth sub-aspect of the second aspect of the present invention, provision can be made that the mount 20 has a hot part 31, proximal to the hot-side substrate 7, and a cold part 32, proximal to the cold-side substrate 8. The previously mentioned through-openings 21 are formed here both in the hot part 31 and also in the cold part 32. Furthermore, it is shown in FIGS. 11 and 12 that in the hot part 31 and in the cold part 32 likewise the recesses 29, explained with reference to FIG. 10, can be formed.

An embodiment is advantageous, in which the hot part 31 is fastened to the hot-side substrate 7, whereas the cold part 32 is adjustable relative to the hot part 31 along the thermoelectric elements 2. In other words, in this structural form, the cold part 32 is not fastened to the cold-side substrate 8. In the reverse type of construction, on the other hand, the cold part 32 is fastened to the cold-side substrate 8, whereas the hot part 31 is not fastened to the hot-side substrate 7, but rather is arranged so as to be adjustable relative to the cold part 32 along the thermoelectric elements 2. In FIG. 11, purely by way of example, a guide 33 is shown, which improves the adjustability of hot part 31 and cold part 32 relative to one another. In FIG. 12, on the other hand, a connection 34 is shown between the hot part 31 and the cold part 32, which can be configured so as to be articulated and/or elastic, and which in particular can contain at least one predetermined breaking point 35. The articulated or elastic connection 34 can permit the desired relative movements. Likewise, the predetermined breaking point 35 can break in the case of sufficient force, and can then enable the desired relative adjustment.

As can be seen from FIGS. 11 and 12, furthermore in the region of the thermoelectric elements 2 an intermediate space 36 can be formed between the hot part 31 and the cold part 32, in which intermediate space the hot part 31 and cold part 32 are spaced apart from one another. In the case of a relative adjustment of the hot part 31 with respect to the cold part 32, this distance reduces.

In another embodiment, provision can be made that on the one hand the hot part 31 is securely connected to the hot-side substrate 7, whereas on the other hand the cold part 32 is securely connected to the cold-side substrate 8. Additionally or alternatively, provision can be made that the hot part 31 corresponds to the above-mentioned hot region 25 and accordingly is produced from the first material, whereas the cold part 32 corresponds to the cold region 26 and is produced from the second material.

In the examples of FIGS. 9 and 13 to 15, a further embodiment is shown, which corresponds to a fifth sub-aspect of the second aspect of the present invention. Accordingly, the mount 20 has a positioning region 37, in which the through-openings 21 are exclusively formed. This positioning region 37 is supported via at least one holding region 38 on at least one of the substrates 7, 8, preferably on both substrates 7, 8. In these embodiments, it is noteworthy that the positioning region 37 has a greater distance from the hot-side substrate 7 than from the cold-side substrate 8. Expediently, the distance of the positioning region 37 from the hot-side substrate is at least twice as great as from the cold-side substrate 8. In so far as only a common holding region 38 is provided, this can be configured as a frame which surrounds in a closed manner in circumferential direction the region in which the thermoelectric elements 2 are arranged. Alternatively, a plurality of separate holding regions 38 can also be provided, e.g. in the four corners of a rectangular module 1, which are likewise arranged outside the region of the thermoelectric elements 2. The holding region(s) 38 extend therefore in the previously mentioned circumferential region 24.

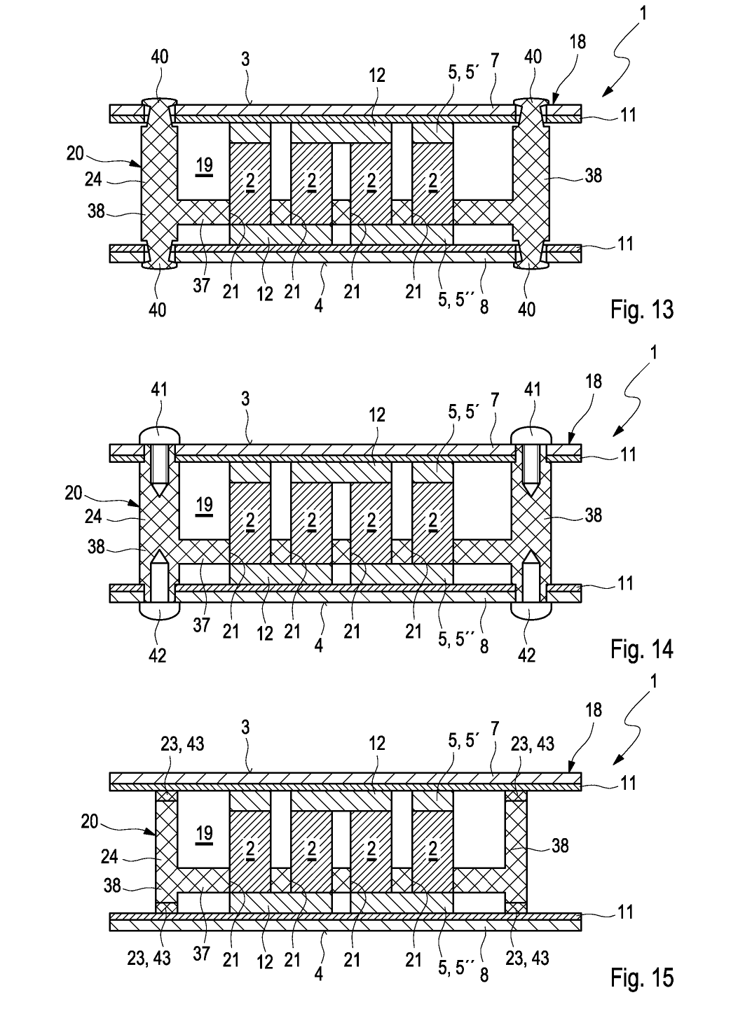

The holding region(s) 38 can be securely connected to the respective substrate 7, 8 in a different suitable manner. FIG. 9 shows plug connections 39 between the holding regions 38 and the hot-side substrate 7. FIG. 9 shows in addition clip connections 40 between the holding regions 38 and the cold-side substrate 8. FIG. 13 shows clip connections 40 between the holding regions 38 and the hot-side substrate 7 on the one hand and the cold-side substrate 8 on the other hand. FIG. 14 shows screwed connections 41 between the holding regions 38 and the hot-side substrate 7 and pin connections 42 between the holding regions 38 and the cold-side substrate 8. In FIG. 15, on the other hand, adhesive connections 43 are shown, by which the holding regions 38 are fixed to the hot-side substrate 7 and to the cold-side substrate 8.

As already explained above, FIGS. 1 and 16 to 18 show one of at least two electric connections 6 of the module 1. Here, according to FIG. 1, it is basically possible to connect the electric connection 6 directly to one of the conductor bridges 5, here to the conductor bridge 5′″, in so far as the material of this conductor bridge 5′″ is suitable for such a connection. Preferably, soldered connections come into use here.

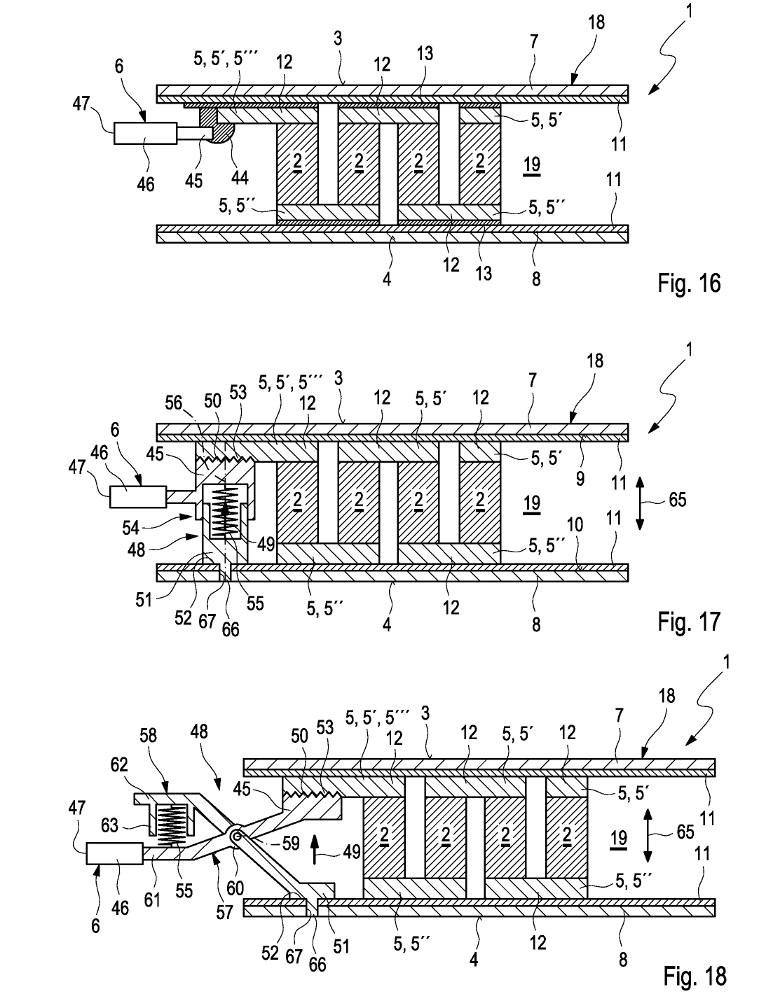

The same also applies to the embodiment shown in FIG. 16, in which the connection 6 is ultimately realized by means of a large-volume soldering point 44, by which a contact element 45 of the connection 6 is securedly connected mechanically in an electrically conductive manner to the respective conductor bridge 5′″ and/or to a metal coating 13 of the insulation 11. On the contact element 45 a connection element 46 is formed, which defines a connection point 47 for connecting an electric cable.

In FIGS. 17 and 18, another embodiment is now shown for the realization of such an electric connection 6, which represents a third aspect of the present invention. For this, the electric connection 6 comprises a pre-stressing arrangement 48, which presses the contact element 45 against the respective conductor bridge 5′″ by means of a pre-stressing force 49. Accordingly, the contact element 45 lies in a pre-stressed manner against an inner side of the respective conductor bridge 5, facing the thermoelectric elements 2, which is also designated here by 5′″. The pre-stressing force 49 is oriented here parallel to the distance direction 65 of the substrates 7, 8.

In the examples of FIGS. 17 and 18, the contact element 45 is equipped, for this, with a contact contour 50, which has elevations which taper and accordingly enable a linear and/or punctiform contacting with the conductor bridge 5. In the sectional views which are shown, a sawtooth-shaped profile can be seen. Accordingly, the contact contour 50 has a plurality of parallel, tapering webs and/or a plurality of tapering pyramids or cones. In so far as here a soft material is used for the conductor bridge 5 or respectively its bridge bodies 12, the contact contour 50 can penetrate into the surface of the conductor bridge 5 and can thereby produce a particularly intimate contact.

The pre-stressing arrangement 48 pre-stresses the contact element 45 in the direction of the one substrate, here in the direction of the hot-side substrate 7, against the respecting conductor bridge 5 and rests here against the other substrate, here against the cold-side substrate 8. In addition, the pre-stressing arrangement 48 rests parallel to the distance direction of the substrates 7, 8 aligned to the contact element 45 against the cold-side substrate 8.

Expediently, the pre-stressing arrangement 48 has a support element 51, which is supported against the cold-side substrate 8. The support element 51 rests here in a support point 52 on the cold-side substrate 8. In contrast thereto, the contact element 45 rests in a contact point 53 on the respective conductor bridge 5.

In the embodiment shown in FIG. 17, the support element 51 and the contact element 45 are guided on one another in a longitudinally adjustable manner. In particular, a telescopic guide 54 is formed for this between the support element 51 and the contact element 45. This longitudinal guide or respectively the telescopic guide 54 is oriented here parallel to the pre-stressing force 49, which in turn extends parallel to the distance direction 65 of the two substrates 7, 8.

In both embodiments, the pre-stressing arrangement 48 has a spring element 55, which is compressed for generating the pre-stressing force 49. Therefore this is a compression spring.

In the example of FIG. 17, the spring element 45 is positioned so that it rests on the one hand against the support element 51 and on the other hand against the contact element 45. In addition, the spring element 55 is aligned here centrically to an imaginary straight connection line 56, which leads directly from the contact point 53 to the support point 52. This straight connection line 56 extends here parallel to a distance direction 65 of the substrates 7, 8, in which the substrates 7, 8 are spaced apart from one another. In particular, the spring element 55 is arranged here within the telescopic guide 54.

In the example of FIG. 18, the pre-stressing arrangement 48 has a contact lever 57, which has the contact element 45, and a support lever 58, on which the support element 51 is formed. The contact lever 57 and support lever 58 are mounted swivellably to one another about a swivel axis 59. A corresponding bearing is designated here by 60. The swivel axis 59 extends perpendicularly to the distance direction 65 of the substrates 7, 8 and in FIG. 18 stands perpendicularly on the plane of the drawing. The spring element 55 is supported on the contact lever 57 and on the support lever 58 on a side of the swivel axis 59 facing away from the contact element 45 and from the support element 51, and namely in a compressed state, in order to generate the pre-stressing 49. The connection point 47 is arranged here at an end 61 of the connection lever 57 remote from the connection element 45. A guide 63 for the spring element 55 is formed on the support lever 58 at an end 62 remote from the support element 52.

In the embodiments shown in FIGS. 17 and 18, the support element 51 has in addition a pin 66, which projects on a side of the support element 51 facing away from the hot-side substrate 7, and engages into a pin mount 67 formed on the cold-side substrate 8. Whereas the contact element 45 and the possibly present contact lever 57 consist of an electrically conductive material, preferably of a metal, the support element 51 and the possibly present support lever 58 can consist of an electrically insulating material, preferably of a plastic.

1. A thermoelectric module, comprising:
a plurality of thermoelectric elements arranged spaced apart from one another between a hot side and a cold side;
a plurality of conductor bridges for electrically interconnecting the plurality of thermoelectric elements and for contacting with at least one electric connection;
a hot-side substrate defining the hot side;
a cold-side substrate defining the cold side;
wherein the at least one electric connection includes a contact element, and wherein the contact element is pre-stressed via a pre-stressing arrangement and lies against at least one conductor bridge of the plurality of conductor bridges.

2. The module according to claim 1, wherein the pre-stressing arrangement pre-stresses the contact element against the at least one conductor bridge in a direction of one of the hot-side substrate and the cold-side substrate and rests against the other of the hot-side substrate and the cold-side substrate.

3. The module according to claim 2, wherein the pre-stressing arrangement rests against the other of the hot-side substrate and the cold-side substrate parallel to a distance direction of the hot-side substrate and the cold-side substrate aligned to the contact element.

4. The module according to claim 2, wherein the pre-stressing arrangement includes a support element, the support element being supported against the other of the hot-side substrate and the cold-side substrate.

5. The module according to claim 4, wherein the support element is guided in a longitudinally adjustable manner on the contact element.

6. The module according to claim 4, further comprising a telescopic guide disposed between the support element and the contact element.

7. The module according to claim 4, wherein the pre-stressing arrangement further includes a spring element arranged to rest on one side against the support element and on another side against the contact element.

8. The module according to claim 7, wherein the spring element is arranged centrically to a straight connection line, and wherein the straight connection line leads directly from a contact point the contact element lies against the at least one conductor bridge to a support point where the support element rests against the other of the hot-side substrate and the cold-side substrate.

9. The module according to claim 6, wherein the pre-stressing arrangement further includes a spring element arranged in the telescopic guide.

10. The module according to claim 4, wherein the pre-stressing arrangement further includes a contact lever and a support lever mounted swivellably to one another about a swivel axis running perpendicularly to the distance direction, and wherein the contact element is disposed on the contact lever and the support element is disposed on the support lever.

11. The module according to claim 10, wherein the pre-stressing arrangement further includes a spring element supported in a pre-stressed manner on the contact lever and on the support lever on a side of the swivel axis facing away from the contact element and from the support element.

12. The module according to claim 10, wherein at least one of the contact lever and the support lever includes a connection point for connecting an electric cable disposed at an end remote from the contact element and from the support element.

13. The module according to claim 4, wherein the support element includes a projecting pin disposed on an outer side facing away from the one of the hot-side substrate and the cold-side substrate, and wherein the projecting pin engages into a pin mount disposed on the other of the hot-side substrate and the cold-side substrate.

14. The module according to claim 1, further comprising a housing, wherein the hot-side substrate and the cold-side substrate define a component of the housing and wherein the housing contains a hermetically closed interior and the plurality of thermoelectric elements are arranged in the hermetically closed interior.

15. The module according to claim 1, wherein at least one of the hot-side substrate is a component of a wall of a hot channel for directing a heating fluid and the cold-side substrate is a component of a wall of a cooling channel for directing a cooling fluid.

16. The module according to claim 1, wherein the pre-stressing arrangement pre-stresses the contact element against the at least one conductor bridge in a direction of the hot-side substrate and rests against the cold-side substrate.

17. The module according to claim 16, wherein the pre-stressing arrangement includes a support element supported against the cold-side substrate.

18. The module according to claim 17, further comprising a telescopic guide disposed between the support element and the contact element.

19. The module according to claim 18, wherein the pre-stressing arrangement further includes a spring element arranged in the telescopic guide.

20. A thermoelectric module, comprising:
a first substrate and a second substrate;
a plurality of thermoelectric elements arranged spaced apart from one another between the first substrate and the second substrate, wherein the first substrate is one of a hot-side substrate and a cold-side substrate, and the second substrate is the other of the hot-side substrate and the cold-side substrate;
at least one electric connection;
a plurality of conductor bridges arranged to electrically interconnect the plurality of thermoelectric elements and to contact the at least one electric connection;
the at least one electric connection including a contact element, wherein the contact element is pre-stressed via a pre-stressing arrangement and lies against at least one conductor bridge of the plurality of conductor bridges; and
wherein the pre-stressing arrangement pre-stresses the contact element against the at least one conductor bridge in a direction towards the first substrate and rests against the second substrate.
